(19) United States
(12) Patent Application Publication
(10) Pub. No.: US 2009/0096001 A1
(43) Pub. Date: Apr. 16, 2009

(54) Integrated Circuit and Method of Manufacturing the Same

(75) Inventors: Frank Ludwig, Dresden (DE); Kerstin Porschatis, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/872,230

(22) Filed: Oct. 15, 2007

(51) Int. Cl. H01L 29/94; H01L 21/76

(52) U.S. Cl. 257/303; 438/424; 257/E21.54; 257/E29.345

(57) ABSTRACT

A method of manufacturing an integrated circuit includes: forming a trench in a substrate, forming a high-k dielectric layer lining the trench, and removing a section of the high-k dielectric layer from the trench via an isotropic dry etch process.

### BACKGROUND

Integrated circuits or semiconductor devices, for example DRAM devices or non-volatile electric devices, may comprise capacitor structures or other charge storing structures. In order to achieve a high capacitance, the use of high-k dielectrics is recently forced in manufacturing capacitors or integrated circuits, wherein such high-k materials may be used as the dielectric material or as a charge storing layer. High-k dielectric materials have a permittivity of at least three times that of silicon dioxide. However, it is difficult to pattern layers of such materials, especially if the high-k dielectric material has a crystalline structure and if the high-k material which has to be removed or patterned is disposed at a surface which is not accessible for etching processes based upon physical sputtering.

### SUMMARY

Described herein is a method of manufacturing an integrated circuit. The method comprises: forming a trench in a substrate, forming a high-k dielectric layer lining the trench, and removing a section of the high-k dielectric layer from the trench via an isotropic dry etch process.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The accompanying drawings are included to provide a further standing of embodiments of the invention and are incorporated in and constitute a part of this specification. The drawings illustrate the embodiments of the present invention and together with the description serve to explain the principles. Emphasis is placed upon showing the principles. Other embodiments of the invention and many of the intended advantages will be easily appreciated, as they become better understood by reference to the following detailed description. The elements of the drawings are not necessarily to scale relative to each other. Like reference numbers designate corresponding similar parts.

FIG. 1 illustrates a flow diagram of a method of manufacturing an integrated circuit.

FIGS. 2A-2D illustrate cross-sectional views of an integrated circuit at different stages of processing according to an embodiment of the method.

FIGS. 3A-3D illustrate cross-sectional views of another integrated circuit at different stages of processing according to another embodiment of the method.

FIGS. 4A-4D illustrate cross-sectional views of another integrated circuit at different stages of processing according to another embodiment of the method.

FIGS. 5A-5E illustrate cross-sectionals views of another integrated circuit at different stages of processing according to another embodiment of the method.

### DETAILED DESCRIPTION

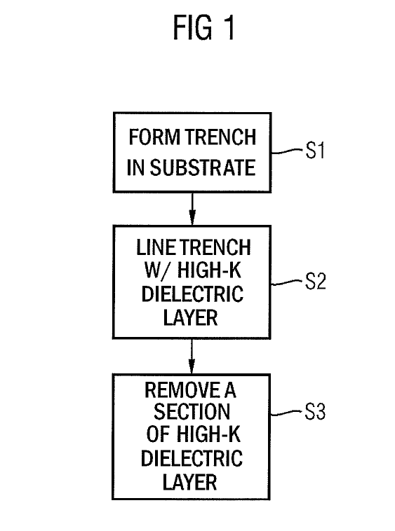

FIG. 1 shows an embodiment of a method of manufacturing an integrated circuit.

First a trench is formed in a substrate (S1). The term “substrate” used in the following description may include any substrate or layer used in manufacturing an integrated circuit. The substrate may be a semiconductor substrate, an insulating layer, a conductive layer, or a layer stack comprising insulating or conductive or semiconductor layers. The term “semiconductor substrate” may include any semiconductor based structure that has a semiconductor surface. Such a structure is to be understood to include silicon, silicon-on-insulator (SOI), silicon-on-sapphire (SOS), doped and undoped semiconductors, epitaxial layers of silicon supported by a base semiconductor foundation, and other semiconductor structures. The semiconductor needs not to be silicon based. The semiconductor could as well be silicon-germanium, germanium or gallium-arsenide.

The trench formed in the substrate may have an arbitrarily cross-section, like for instance a circular, an elliptical, a rectangular, or a polygon shaped cross-section. A high-k dielectric layer is formed such that it lines the trench (S2). The high-k dielectric layer covers a whole surface of the trench. A dielectric material having a permittivity of at least about 3 times that of silicon dioxide is considered as a high-k dielectric. Examples of high-k dielectrics include: silicates, aluminates, titanates, and metal oxides. Examples of silicate high-k dielectrics include: silicates of Ta, Al, Ti, Zr, Y, La and Hf, (e.g., HfSiOx, HfSiOxNy, ZrSiOx, ZrSiOxNy, TaSiOx, TiSiOx, AlSiOx), including Zr and Hf doped silicon oxides and silicon oxynitrides. Examples of aluminates include refractory metal aluminates, such as compounds of Zr and Hf, and aluminates of Lanthanide series metals, such as La, Lu, Eu, Pr, Nd, Gd, and Dy. Examples of titanate high-k dielectrics include BaTiO₃, barium-strontium-titanate (BST), Lead-lanthanum-zirconium-titanate (PLZT), PZT, SrTiO₃ and PbZrTiO₃. Examples of metal oxide high-k dielectrics include oxides of refractory metals, such as Zr and Hf, and oxides of Lanthanide series metals, such as La, Lu, Eu, Pr, Nd, Gd and Dy. Additional examples of metal oxide high-k dielectrics include: Al₂O₃, TiO₂, Ta₂O₅, Nb₂O₅ and Y₂O₃. Nevertheless, the high-k dielectric layer may be a layer stack comprising different high-k dielectric materials or may comprise a combination of materials described above. The high-k dielectric layer may be deposited using any of a variety of processes, including but not limited to: chemical vapor deposition (CVD), metal-organic chemical vapor deposition (MOCVD), atomic layer deposition (ALD), atomic layer chemical vapor deposition (ALCVD), low pressure chemical vapor deposition (LPCVD), sputtering, anodization, or any combination thereof, for example.

A section of the high-k dielectric layer is removed from the trench using an isotropic dry etch process (S3). The isotropic dry etch process is characterized by a chemical removal of the high-k dielectric material rather than by a physical sputter removal. It is possible to remove the high-k dielectric layer from a sidewall section of the trench wherein the sidewall section extends in a direction having an angle smaller than 5° to a direction perpendicular to a surface of the substrate. The sidewall section may extend in a direction having an angle smaller than 2° to the direction perpendicular to the surface of the substrate. That portion of the trench corresponding to the removed section of the high-k dielectric layer may comprise sidewall sections extending almost perpendicular to the substrate surface. Such sidewall sections are almost not accessible for dry etch processes based upon sputtering, especially if the trench has an aspect ratio larger than 8. Furthermore, it is difficult for sputtering particles to reach into a depth larger than 8 times a width of the trench. That is, if the high-k dielectric layer has to be removed from a section of the trench extending to a higher depth, then a chemical removal and therefore an isotropic dry etch process may be used.

The isotropic dry etch process comprises three stages of the process: adsorption of etch species at a surface of the high-k dielectric layer, a chemical reaction between the etch species and the high-k dielectric material, and a desorption process of reaction products.

The dry etch process can be carried out in a plasma etching tool and uses an etching chemistry based upon chlorine and borontrichloride. The process may be performed by a source power of about 500 to 3000 Watt and at a pressure of about 4 to 20 mTorr. The gas flow may include 10 to 100 sccm of chlorine, 10 to 100 sccm of BCl₃, 0 to 20 sccm of O₂, and 0 to 100 sccm of a dilution gas, such as argon, N₂ or helium. The oxygen is used to remove a polymer formed at the surface of the high-k dielectric layer during the etch process. The polymer passivates the surface of the high-k dielectric layer and would cause an etch stop if it is not removed. The oxygen may be added to the gas flow only temporarily or may be added continuously. In order to achieve an isotropic dry etch process, a bias power of at most 50 W is applied to a cathode, where the substrate is disposed on. The bias power may be for instance 0 W, or may have a value between 0 and 50 W. During the dry etch process the cathode may be held at a temperature of at least 300° Celsius, for instance at a temperature of 350° C. The high cathode temperature is used to facilitate a desorption process of reaction products.

The described isotropic dry etch process is suited for etching a crystalline high-k dielectric layer which may result from a temperature process carried out before the dry etch process. This temperature process is performed at a temperature higher than the crystallization temperature of the high-k dielectric material. Hafnium silicate, for example, has a crystallization temperature of about 750° C. Such a process may for instance be a deposition process of a masking material used as etching mask for removing the section of the high-k dielectric layer, a deposition process of other materials, for instance carbon, or a temperature process for annealing defects in the substrate or for driving in dopants into sections of the substrate. Nevertheless, the described dry etch process may be used for etching an amorphous high-k dielectric layer as well.

According to an embodiment, the method of manufacturing an integrated circuit may further comprise forming a first and a second capacitor electrode within the trench, wherein the high-k dielectric layer is formed between the first and the second capacitor electrode. Thus a capacitor may be formed within the trench, wherein the capacitor may be a trench capacitor formed beneath a substrate surface of the semiconductor substrate or may be a stacked capacitor formed above the substrate surface of the semiconductor substrate.

According to another embodiment, the method further comprises forming an access transistor comprising a first and a second source/drain region, wherein the first source/drain region is electrically coupled to one of the first or the second capacitor electrode. Thus a memory cell may be formed comprising the access transistor and a storage capacitor formed within the trench. A plurality of memory cells may form a memory device, for example, a DRAM memory device. Nevertheless, other memory devices comprising other memory cells, which may or may not comprise an access transistor, may be formed, as for example a FRAM (Ferroelectric Random Access Memory) device. Each memory cell of the memory device may be addressed by at least one first and one second conductive line formed according to a further embodiment.

According to another embodiment, the described method may be used for manufacturing a transistor, wherein the transistor may for example be formed vertically within the trench, and wherein the high-k dielectric layer may be used as a gate dielectric layer or another dielectric layer of the transistor. Other examples for a transistor, which may be manufactured using the described method, may be a RCAT (Recessed channel array transistor), a FinFET, or a SGT (surrounded gate transistor), a floating gate device, a SONOS (Silicon Oxide Nitride Oxide Silicon) or a NROM (Non-volatile Read Only Memory) transistor. Such transistors may form a memory device or may be comprised by a memory device as well.

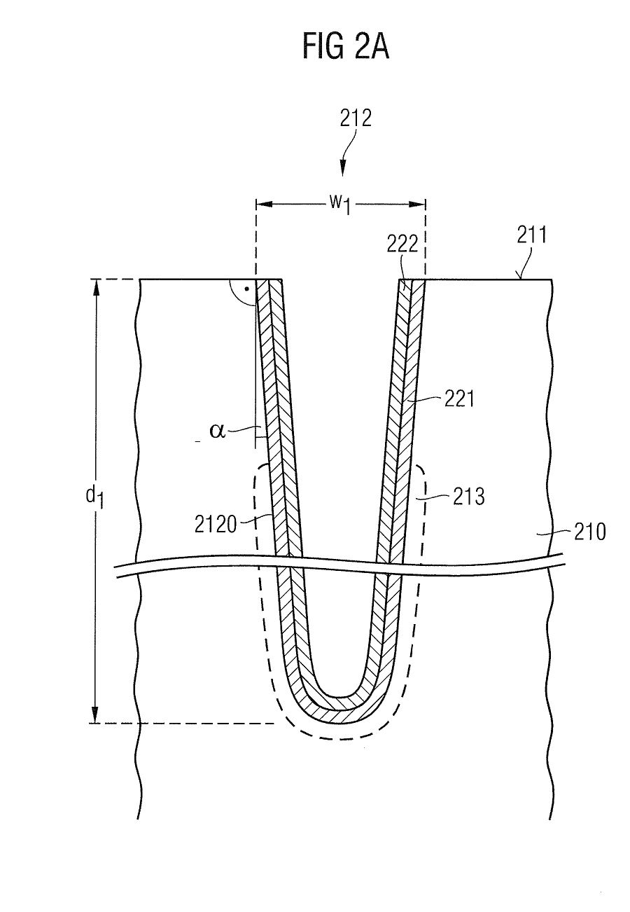

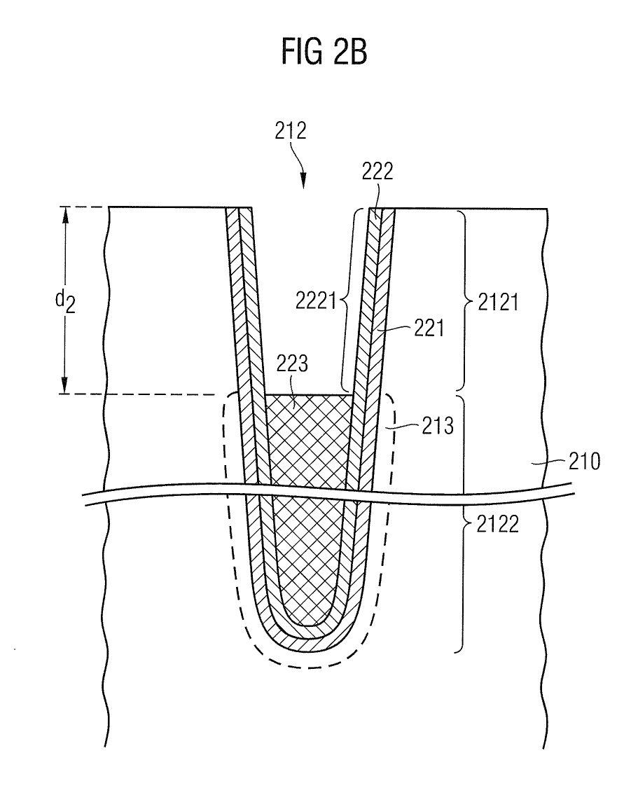

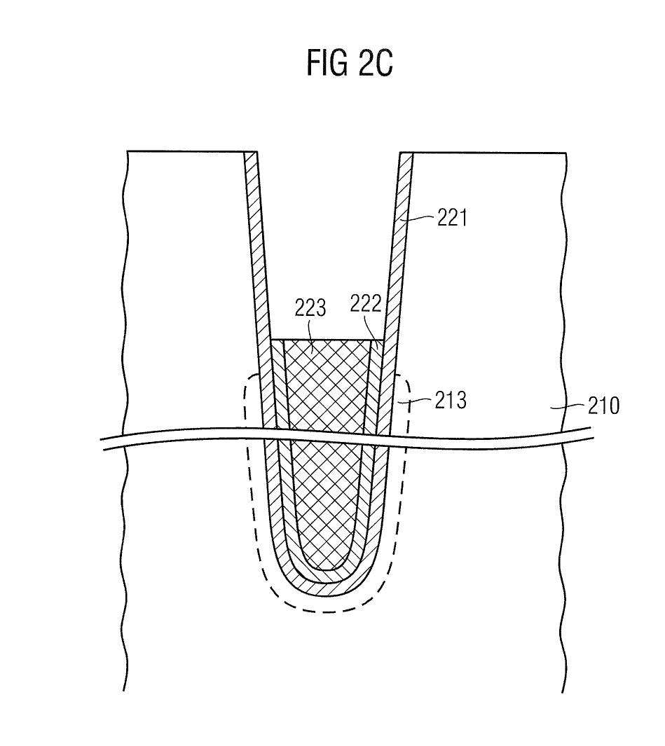

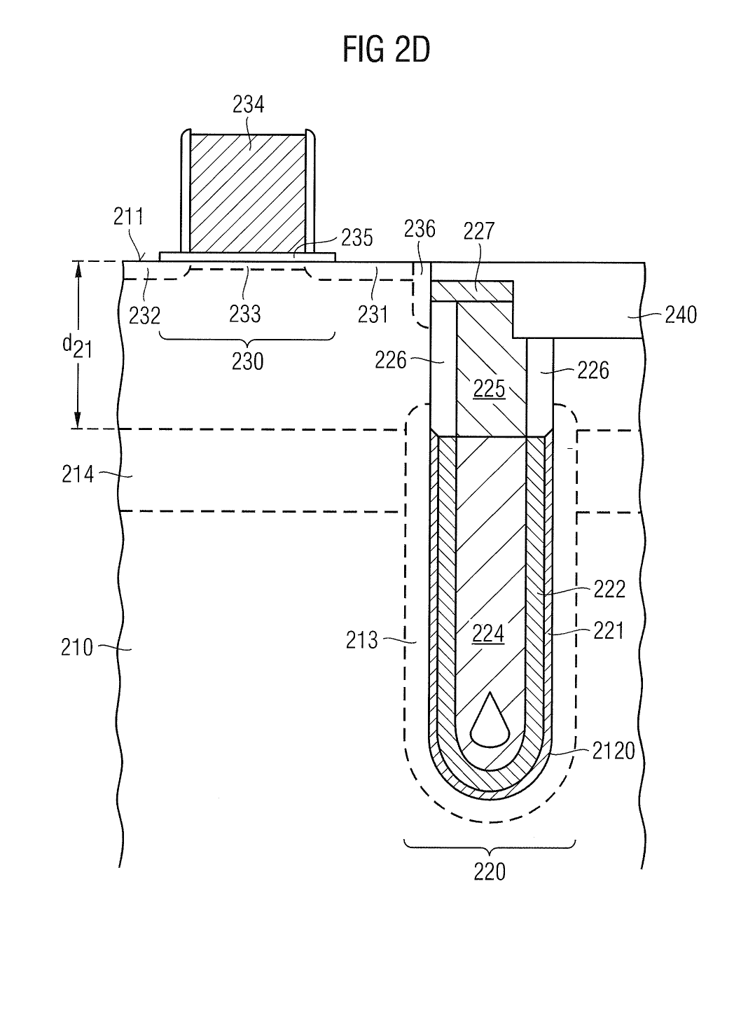

Referring to FIGS. 2A-2D, an embodiment of the method will be explained using cross-sectional views of an integrated circuit at different stages of processing. A substrate 210 having a substrate surface 211 is provided and a trench 212 is formed within the substrate. The term “substrate” used in the following description may include any structure or material such as a semiconductor substrate, an insulating material or a conductive material. The insulating material may be, for example, a silicon oxide or silicon oxynitride layer disposed, for instance, on a semiconductor substrate. The substrate may as well be a conductive layer formed for instance of metal or a conductive layer of a carbide or a nitride, disposed on, for example, a semiconductor substrate. Nevertheless, such an insulating or a conductive layer may be disposed on any other carrier or substrate, like a ceramic or an organic carrier.

Referring to FIG. 2A, the substrate 210 is a semiconductor substrate as described above, wherein the substrate may comprise devices, like transistors, or doped regions within other portions of the substrate. The trench 212 extends from the substrate surface 211 to a depth d1. The depth d1 may be larger than 1 μm. The depth d1 may for instance be larger than 4 μm or larger than 6 μm. The trench 212 may have a width w1, which is the smallest dimension of the trench at the substrate surface 211 in a planar view and is measured at the substrate surface 211. In other words, the trench 212 may extend into a direction perpendicular to the plane of the cross-section shown in FIG. 2A and may have a length measured along that direction at the substrate surface 211 and being larger than the width w1. The width w1 may be larger than 10 nm. The width w1 may be smaller or equal to 90 nm. The aspect ratio of the trench 212, that is the ratio of the depth d1 to the width w1, may be larger than 9. The aspect ratio may for instance be larger than 20. The trench 212 may have a circular, an oval, a rectangular or any other shape in a plane view. The trench 212 has a trench surface 2120 extending within the substrate 210. The trench surface 2120 may extend into the substrate 210 from the substrate surface 211 with an angle α measured between the trench surface 2120 and a direction perpendicular to the substrate surface 211. The profile of the trench surface may be vertical or even reentrant, the angle α may be smaller than 5° and may be negative. At least an upper section of the trench surface 2120 extends almost perpendicular to the substrate surface 211. Furthermore, the trench 212 may comprise sections having a higher width than w1, wherein w1 is measured at the substrate surface 211.

The trench 212 may have the shape of a cylinder, a cone with straight sidewalls, a cone with bowed or waved sidewalls or may have the shape of a bottle with a small trench width near the substrate surface 211 and a larger trench width at a higher trench depth, as for example. The width of the trench 212 and the angle α of the trench surface 2120 to a perpendicular direction to the substrate surface 211 may vary over the depth d1 of the trench 212.

According to an embodiment, a doped region 213 may be formed within the substrate 210 adjacent to a section of the trench surface 2120. This doped region 213 may form a first capacitor electrode of a trench capacitor, which may be formed, or the doped region 213 may be a contact region of a conductive layer 221, which may be formed on the trench surface 2120 within the trench 212.

The conductive layer 221 and also the doped region 213, shown in FIG. 2A, are optional and may be omitted. The conductive layer 221 may be made of any suitable conductive material (e.g., polysilicon, TiN, TiHfN, HfN, TiAlN, TaN, HfAlN or others). The conductive layer 221 may as well be a layer stack comprising different materials. The conductive layer 221 may be formed as a conformal layer on the trench surface 2120.

A high-k dielectric layer 222 is formed within the trench 212 on the conductive layer 221 or on the trench surface 2120 if conductive layer 221 is omitted. The high-k dielectric layer 222 extends from the substrate surface 211 and covers the whole surface of the trench 212. The high-k dielectric layer 222 may be formed as a conformal layer. The material of the high-k dielectric layer 222 may be formed in an amorphous stage on the underlying surface.

The thickness of the conductive layer 221 may be smaller than or equal to 15 nm. The thickness of the high-k dielectric layer 222 may be smaller than or equal to 20 nm. A typical thickness of the high-k dielectric layer 222 may be 8 nm.

Referring to FIG. 2B, a masking material 223 is formed within the trench 212 such that it covers the high-k dielectric layer 222 in a lower section 2122 of the trench 212. A section 2221 of the high-k dielectric layer 222 remains uncovered in an upper section 2121 of the trench 212. The section 2221 extends from the substrate surface 211 to a depth d2 which may be smaller than the depth d1 of the trench 212. The depth d2 may be larger than 500 nm. The ratio of d2 to w1 may be larger than 8.

The masking material 223 may be formed as a material completely filling the trench 212 in the lower section 2122, as shown in FIG. 2B. Nevertheless, the masking material 223 may be formed as a conformal layer covering the high-k dielectric layer 222 in the lower section 2122 of the trench 212. In another embodiment, the masking material 223 can be formed as a layer having varying thicknesses in the lower section 2122 or may be formed as a material filling the lower section 2122 and having one or more voids inside. The masking material 223 may be made of any suitable material having a lower etch rate than the high-k dielectric layer 222 in the following isotropic dry etch process. Examples of such materials may be silicon oxide, silicon nitride, polysilicon, resist materials, carbon, metals or metal oxides as well as metal silicates. The masking material 223 may comprise different materials. By way of example, a polysilicon layer may fill most of the lower section 2122 of the trench 212 and a silicon oxide or silicon nitride layer may cover the polysilicon layer such that the lower section 2122 is completely filled. The masking material 223 may be formed by first filling the whole trench 212 and may be than removed from the upper section 2121 of the trench 212, for instance by a recess etch process. If the process of forming the masking material 223 is performed at a temperature higher than the crystallization temperature of the material of the high-k dielectric layer 222, the material of the high-k dielectric layer 222 may be crystallized. Nevertheless, the material of the high-k dielectric layer 222 may be in an amorphous stage after forming the masking material 223 or may be crystallized by another process as described above.

Thereafter the isotropic dry etch process described above is carried out, thereby removing the section 2221 of the high-k dielectric layer 222 which was not covered by the masking material 223. The masking material 223 may be partially etched as well resulting in a possible removing or deterioration of the high-k dielectric layer 222 in a portion of the lower section 2122 which is adjacent to the upper section 2121.

The resulting structure is shown in FIG. 2C. The surface of the conductive layer 221 or the trench surface 2120, if the conductive layer 221 was omitted, is exposed in the upper section 2121 of the trench 212. In the lower section 2122 of the trench 212, the conductive layer 221 and the high-k dielectric layer 222 are formed on the trench surface 2120. The masking material 223 may be removed after performing the dry etch process or may remain within the trench 212.

If the masking material 223 is a conductive material, as for example polysilicon, the masking material 223 may serve as a second electrode of a capacitor comprising the conductive layer 221 as a first capacitor electrode and the high-k dielectric layer 222 as the capacitor dielectric. Nevertheless, the masking material 223 may be removed and a conductive layer 224 may be formed within the trench 212, as shown in FIG. 2D.

FIG. 2D shows a cross-sectional view of a memory cell comprising a storage capacitor 220 and an access transistor 230. The storage capacitor 220 may be formed by the process described with respect to FIGS. 2A-2C. Following the processing stage shown in FIG. 2C, the masking material 223 is removed from the trench 212 and a conductive layer 224 is formed filling the lower section 2122 of the trench 212. The conductive layer 221 is removed from an upper section of the trench 212. The upper section of the trench 212 extends to a depth d21, which may be the same as the depth d2 or may be smaller than the depth d2. An insulating material 226 is formed at the surface 2120 of the trench 212 in the upper section to insulate a conductive material 225 filling the trench 212 and being in contact with the conductive layer 224.

The access transistor 230 comprises a first and a second source/drain region 231, 232 which may be formed within the substrate 210. A channel region 233 may be formed within the substrate 210 separating the first and second source/drain region 231, 232. A gate electrode 234 may be formed above the substrate surface 211. Nevertheless, the gate electrode 234 may be formed as a buried electrode beneath the substrate surface 211. A gate dielectric 235 insulates the gate electrode 234 from the channel region 233. The first source/drain region 231 is electrically coupled via a doped substrate region 236 to a contact plug 227 formed within the trench 212 and being in contact with the conductive material 225.

Individual memory cells comprising one storage capacitor 220 and one access transistor 230 may be insulated from other memory cells by insulating structures, as for instance shown in FIG. 2D as the insulating material 240. A plurality of memory cells may form a memory cell array, wherein individual ones of the memory cells may be connected by conductive lines. Furthermore, the capacitor electrodes of individual storage capacitors 220 formed by the conductive layer 221 and the doped portion 213 may be connected with each other via a doped portion 214 formed within the substrate 210.

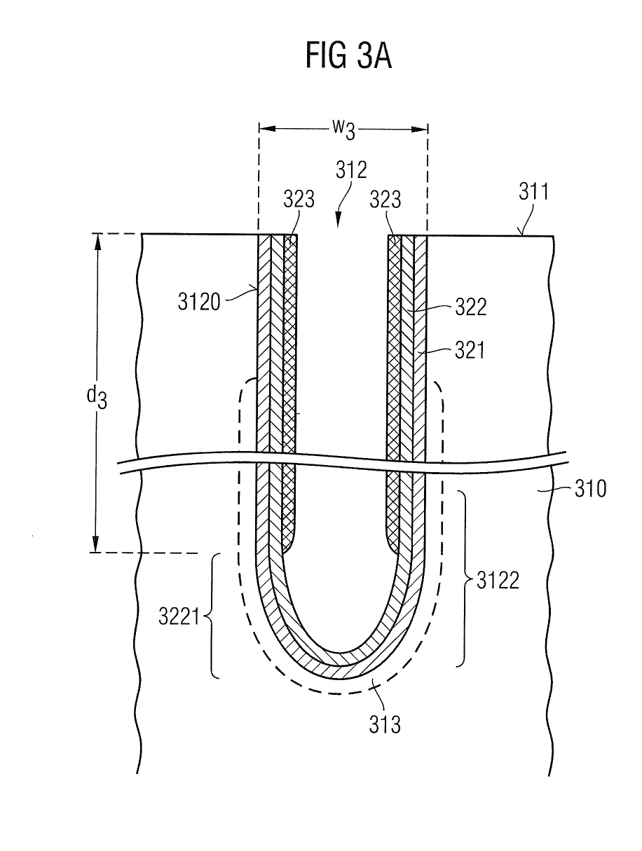

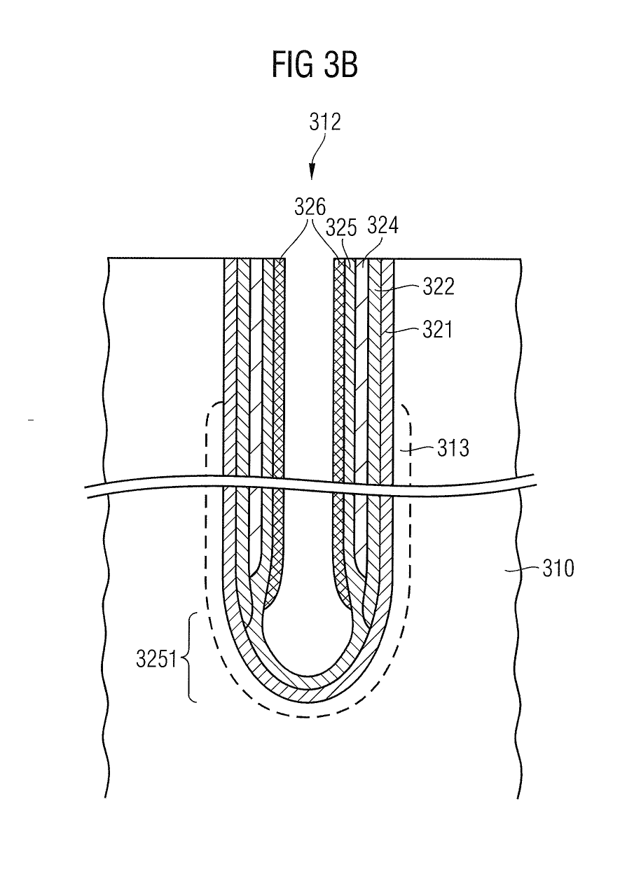

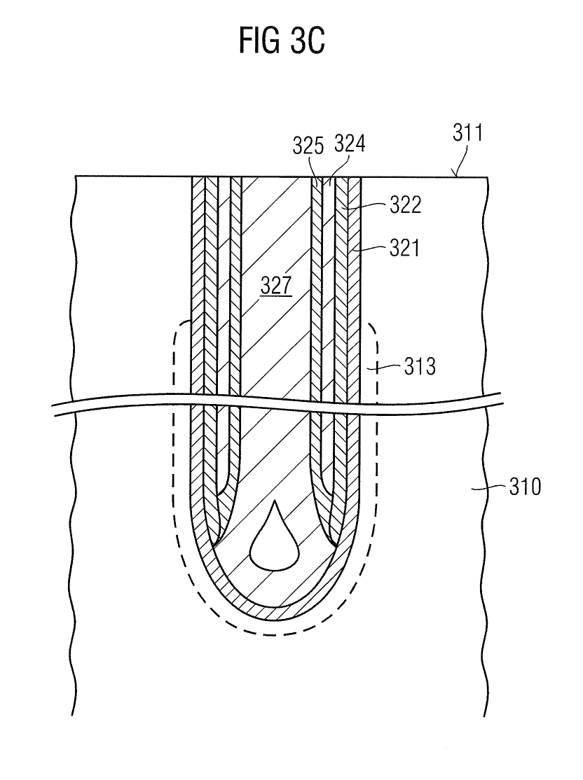

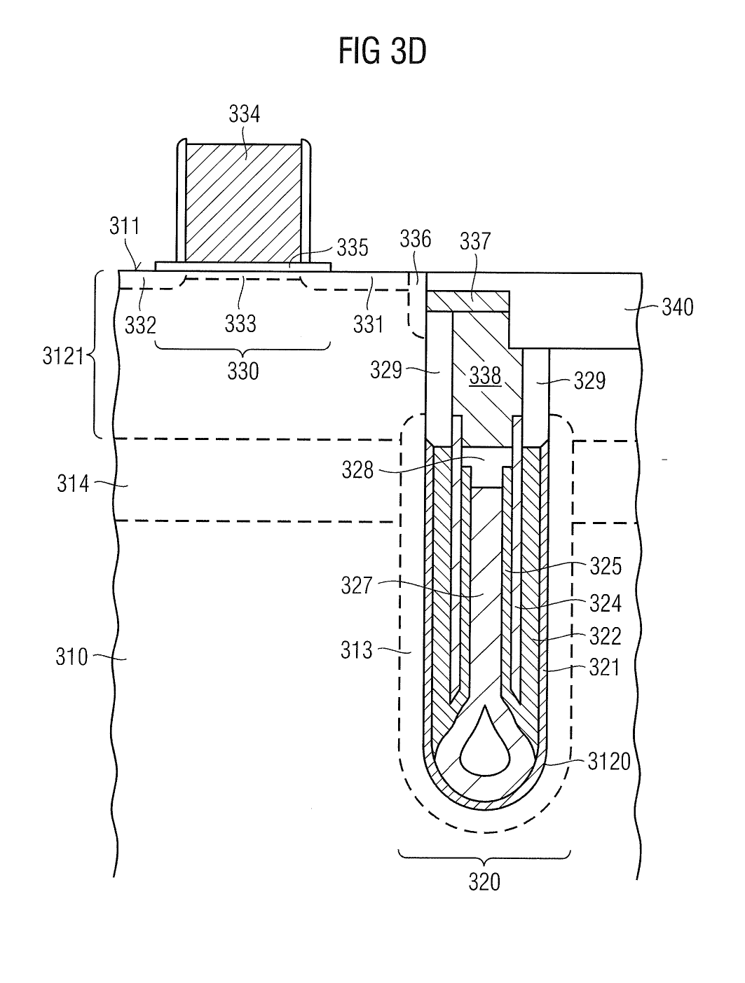

Referring to FIGS. 3A-3D, another embodiment of the method of fabricating an integrated circuit and another embodiment of an integrated circuit comprising a trench capacitor will be explained. A substrate 310, for instance a semiconductor substrate, is provided having a substrate surface 311. A trench 312 is formed in the substrate 310 extending from the substrate surface 311 and having a width w3 being a smallest dimension of the trench 312 in a planar view and being measured at the substrate surface 311. A conductive layer 321 is formed at the trench surface 3120, for instance as a conformal layer. A doped portion 313 may be formed within the substrate 310 adjacent to the substrate surface 3120 in a lower portion of the trench 312. Nevertheless, the conductive layer and/or the doped portion 313 may be omitted. A high-k dielectric layer 322 may be formed as described above on the conductive layer 321 or on the trench surface 3120 if the conductive layer 321 is omitted. The high-k dielectric layer 322 may be formed as a conformal layer extending from the substrate surface 311 and covering the whole surface within the trench 312. A masking layer 323 may be formed on the high-k dielectric layer 322 such that a section 3221 of the high-k dielectric layer 322 in a lower section 3122 of the trench 312 will not be covered. The section 3221 may comprise sections of sidewall portions of the trench 312 and may comprise a bottom portion of the trench 312. The section 3221 extends from a depth d3 measured from the substrate surface 311 to a depth larger than d3. The ratio of d3 to the width w3 may be larger than 8. The masking material 323 may be made of the materials described above and may be formed as a conformal layer which does not completely fill the trench 312. The masking material 323 may be formed by a known process (e.g., an atomic layer deposition process). The resulting structure is shown in FIG. 3A.

Thereafter, a first isotropic dry etch process as described above is performed using the masking layer 323 as an etching mask to remove the section 3221 of the high-k dielectric layer 322 from the trench 312. Thereafter the masking layer 323 may be removed from the trench 312 or may remain within the trench 312 if the masking layer 323 is made of a conductive material. If the masking layer 323 is removed from the trench 312, a conductive layer 324 may be formed on the high-k dielectric layer 322 extending to a smaller depth measured from the substrate surface 311 than the high-k dielectric layer 322. The high-k dielectric layer 322 extends from the substrate surface 311 to the depth d3 smaller than the depth of the trench 312. The conductive layer 324 may be formed as a conformal layer having a thickness of more than 5 nm using an atomic layer deposition process. Nevertheless, the conductive layer 324 may be formed using another process comprising for instance a deposition process and an etching process. A further high-k dielectric layer 325 may be formed on the resulting surface within the trench 312 to cover the conductive layer 324, the high-k dielectric 322 and the conductive layer 321. The further high-k dielectric layer 325 may be made of the same material as the high-k dielectric layer 322 or may be formed of another high-k dielectric material. A masking layer 326 is formed on the further high-k dielectric layer 325 such that it covers the further high-k dielectric layer 325 except in a section 3251 of the further high-k dielectric layer 325. The masking layer 326 does not completely fill the trench 312 and extends from the substrate surface 311 to a depth larger than the depth of the conductive layer 324 but smaller than the depth of the trench 312. The resulting structure is shown in FIG. 3B.

Thereafter, a second isotropic dry etch process is performed to remove the section 3251 of the further high-k dielectric layer 325 from the trench 312 using the masking layer 326 as an etching mask. The isotropic dry etch process is carried out as described above. After the isotropic dry etch process, the further high-k dielectric layer 325 covers the conductive layer 324 completely and extends to a depth deeper than the depth to which the conductive layer 324 extends. Within the trench 312 the surface of the conductive layer 321 or the trench surface 3120, if the conductive layer 321 is omitted, is exposed in a lower section of the trench 312. The masking layer 326 may be removed from the trench 312 or may remain within the trench 312.

According to an embodiment, a conductive material 327 is formed inside the trench 312, such that it is in contact with the conductive layer 321 or the trench surface 3120, if the conductive layer 321 is omitted. The conductive material 327 may completely fill the trench 312 or may be formed as a conformal layer. The resulting structure, shown in FIG. 3C, is a capacitor, wherein the conductive layers 321 and 327 may serve as a first capacitor electrode and the conductive layer 324 may serve as a second capacitor electrode. The first and the second capacitor electrode may be separated from each other by the high-k dielectric layers 322 and 325.

Such a capacitor may be used as a storage capacitor 320 in a memory cell as shown in FIG. 3D. The memory cell may comprise the storage capacitor 320 formed as a trench capacitor within the substrate 310 and an access transistor 330 at least partially formed within the substrate 310. The access transistor 330 may comprise a first and a second source/drain region 331, 332, which may be formed within the substrate 310. A channel region 333, a gate electrode 334 and a gate dielectric 335 are formed as described with respect to FIG. 2D. The first source/drain region 331 may be electrically coupled to the conductive layer 324 forming the second capacitor electrode of the storage capacitor 320 by a doped substrate region 336, a contact plug 337 and a conductive material 338, wherein the contact plug 337 and the conductive material 338 are formed within the trench 312. The conductive material 338 is insulated from the substrate 310 by an insulating material 329 and from the conductive layer 327 by an insulating material 328. In order to form the insulating material 328 and 329 and the conductive material 338 and the contact plug 337, the conductive layers 321, 324, and 327 as well as the high-k dielectric layers 322 and 325 may be removed from an upper section 3121 of the trench 312, wherein the conductive layers 321 and 327 are removed to a larger depth than the conductive layer 324. The isotropic dry etch process described with respect to FIGS. 2A-2C may be used to remove the high-k dielectric layers 322 and 325 from the upper section 3121 of the trench 312.

As described with respect to FIG. 2D, individual memory cells may be insulated from neighboring memory cells by insulating structures, wherein one insulating structure 340 is shown in FIG. 3D. Doped portions 313 of individual memory cells may be connected with each other via a doped substrate portion 314.

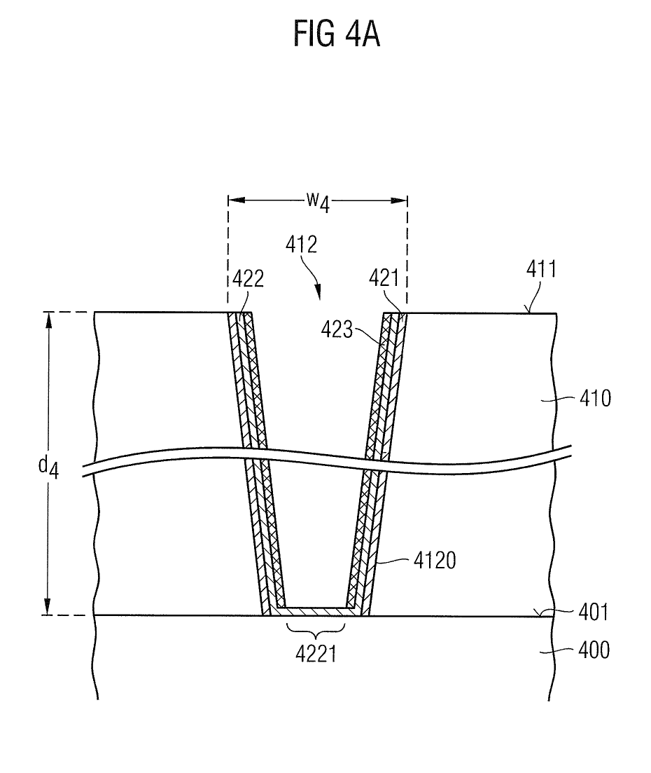

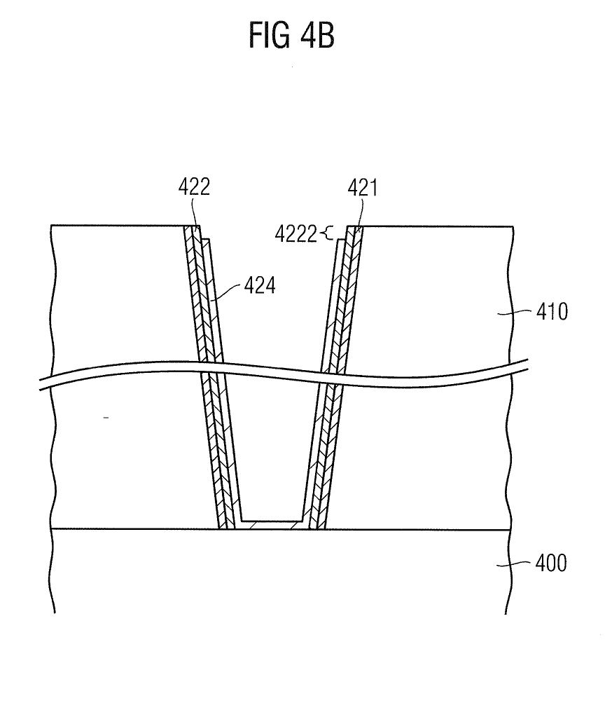

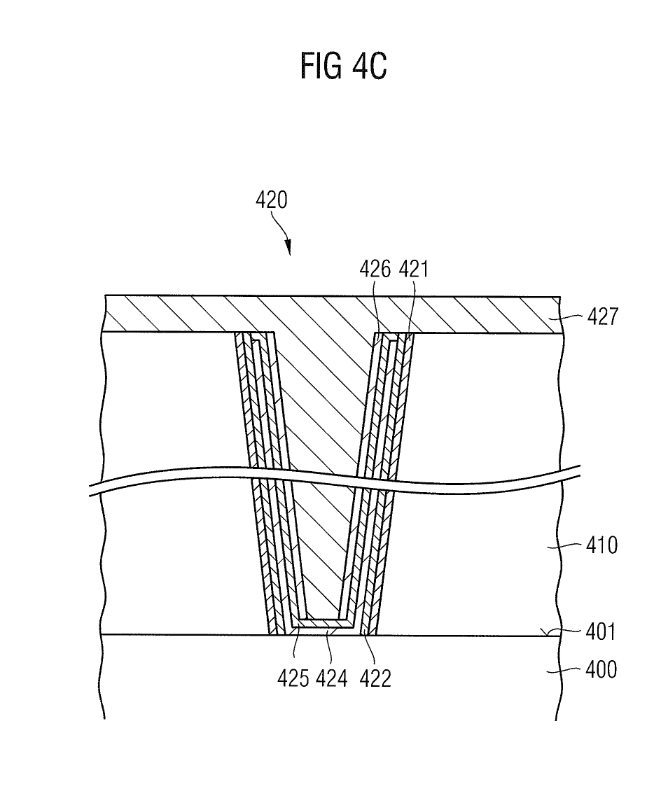

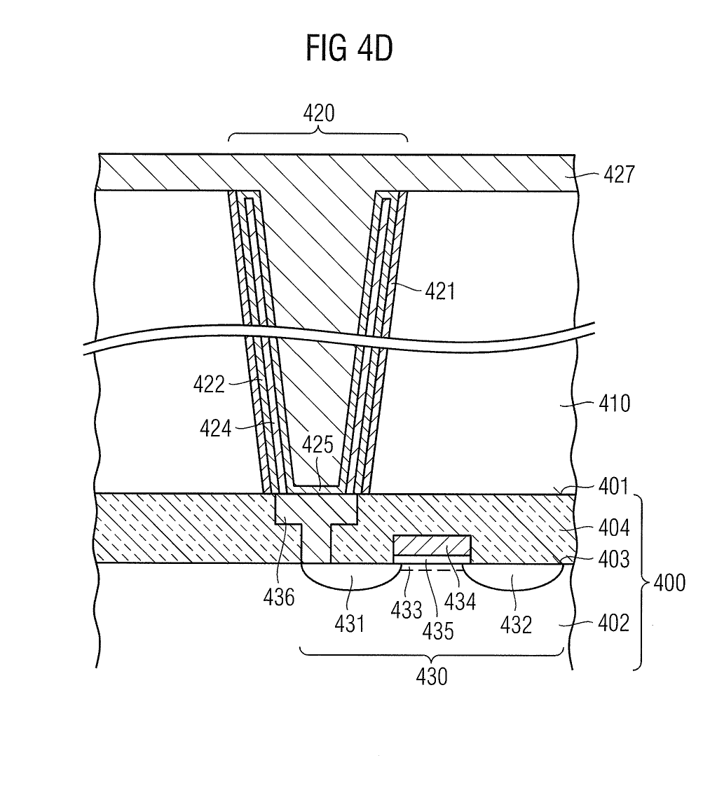

Referring to FIGS. 4A-4D, another embodiment will be explained. A substrate 410 is provided on a work piece 400 having a work piece surface 401. The substrate 410 may for instance be an insulating layer formed on top of a work piece 400. For example, the substrate 410 may be a silicon oxide or an oxynitride layer, and the work piece 400 may comprise a semiconductor substrate, for instance a silicon substrate. Nevertheless, the substrate 410 may be a layer stack comprising layers of different insulating materials, as for instance carbon, silicon oxides or metal oxides, nitrides or others. A trench 412 is formed in the substrate 410, wherein the trench 412 may extend from a substrate surface 411 to the work piece surface 401. The substrate 410 may have a thickness d4, and the trench 412 may extend over the whole thickness of the substrate 410. Thus, d4 may be the depth of the trench 412 measured from the substrate surface 411 as well. The trench 412 may have a width w4 measured at the substrate surface 411 and being the smallest dimension of the trench 412 at the substrate surface 411 in a planar view. In other words, the trench 411 may extend into a direction perpendicular to the plane of the cross-section shown in FIG. 4A and may have a length measured along that direction at the substrate surface 411 and being smaller than the width w4. The trench 412 may be formed with a shape in a plane view and in a cross-sectional view as described above. The depth d4 may be larger than 2 μm, and the width w4 may be smaller than 90 nm. The aspect ratio of trench 412, that is the ratio of the depth d4 to the width w4, may be larger than 8.

As is shown in FIG. 4A, a conductive layer 421 is formed at a trench surface 4120 leaving a bottom portion of the trench 412 uncovered. By way of example, the conductive layer 421 may be formed as a conformal layer covering the trench surface 4120 and may be removed from the bottom portion of the trench 412. In another embodiment, the conductive layer 421 may be formed by a process, for instance an atomic layer deposition (ALD) process which leaves the bottom portion of the trench 412 uncovered. A high-k dielectric layer 422 is formed on the conductive layer 421 and the exposed work piece surface 401 within the trench 412. Layers 421 and 422 may be formed as layers having essentially the same thickness over their extension and may comprise materials as described above. The thickness of the conductive layer 421 may be smaller than 30 nm. The thickness of the high-k dielectric layer may be smaller than 20 nm. The high-k dielectric layer 422 covers the bottom portion of the trench 412. A masking layer 423 is formed on the high-k dielectric layer 422 within the trench 412, wherein a section 4221 of the high-k dielectric layer 422 is not covered by the masking layer 423. The section 4221 is arranged at the bottom portion of the trench 412. The resulting structure is shown in FIG. 4A.

An isotropic dry etch process as described above is performed to remove the section 4221 of the high-k dielectric layer 422 from the trench 412. In the result, the work piece surface 401 is exposed at the bottom portion of the trench 412. A conductive layer 424 is formed on the resulting surface within trench 412. The conductive layer 424 covers the high-k dielectric layer 424 and the exposed work piece surface 401. The conductive layer 424 may be formed as a conformal layer having a thickness as described above with respect to the conductive layer 421 and may be made of the same conductive material as layer 421 or of a different conductive material. The conductive layer 424 may be removed from an upper section 4222 of the high-k dielectric layer 422, wherein the section 4222 extends from the substrate surface 411. According to another embodiment, the conductive layer 424 may remain at the upper portion 4222. The resulting structure is shown in FIG. 4B.

Referring to FIG. 4C, a further high-k dielectric layer 425 may be formed within trench 412 such that it covers the whole surface of the conductive layer 424 and that it is connected with the high-k dielectric layer 422. The further high-k dielectric layer 425 may be formed as a conformal layer made of the materials described above and with a thickness as described above. Subsequently, a conductive layer 426 may be formed at the high-k dielectric layer 425. The conductive layer 426 may be formed as a conformal layer covering the whole surface of the further high-k dielectric layer 425. Nevertheless, the conductive layer 426 may be formed only at sidewall portions of the trench 412 such that a bottom portion of the further high-k dielectric layer 425 remains uncovered. According to another embodiment, the conductive layer 426 may be omitted at all. The conductive layer 426 may be formed of conductive materials and with a thickness as described above with respect to the conductive layers 421 and 424. The remaining trench 412 may be filled with a conductive material 427 which may electrically connect the conductive layers 421 and 426 as shown in FIG. 4C.

The resulting capacitor 420 comprises a first capacitor electrode formed by the conductive layer 424 and a second capacitor electrode formed by the conductive layers 421 and 426 and/or 427, wherein the first and the second capacitor electrodes are separated from each other by the high-k dielectric layers 422 and 425. Note, that the work piece 400 has to be formed in an upper portion adjacent to the work piece surface 401 such, that the conductive layer 421 and the conductive layer 424 are electrically insulated from each other.

Referring to FIG. 4D, an embodiment of a memory cell comprising a storage capacitor 420 and an access transistor 430 is shown. The storage capacitor 420 is almost similar to that shown in FIG. 4C except that the conductive layer 424 is not formed as a layer having a bottom portion adjacent to the work piece surface 401. Furthermore, the conductive layer 426 is omitted. Nevertheless, the conductive layers 424 and 426 may be formed in the same way as shown in FIG. 4C. The access transistor 430 is at least partially formed within a semiconductor substrate 402 being a part of the work piece 400 and having a semiconductor substrate surface 403. The access transistor 430 comprises a first and a second source/drain region 431, 432 which may be formed as doped regions within the semiconductor substrate 402. A channel region 433 is formed within the semiconductor substrate 402 and separates the first and the second source/drain region 431, 432. A gate electrode 434 is formed above the semiconductor substrate surface 403. A gate dielectric layer 435 insulates the gate electrode 434 from the channel region 435. In another embodiment, the gate electrode may be formed as a buried gate electrode beneath the semiconductor substrate surface 403. The work piece 400 further comprises an insulating layer 404 formed on top of the semiconductor substrate surface 403. A surface of the insulating layer 404 forms the work piece surface 401. The second capacitor electrode of the storage capacitor 420 formed by the conductive layer 424 is electrically coupled to the first source/drain region 431 of the access transistor via a contact plug 436 comprising a conductive material. The storage capacitor 420 is formed as a stacked capacitor above the semiconductor substrate surface 403.

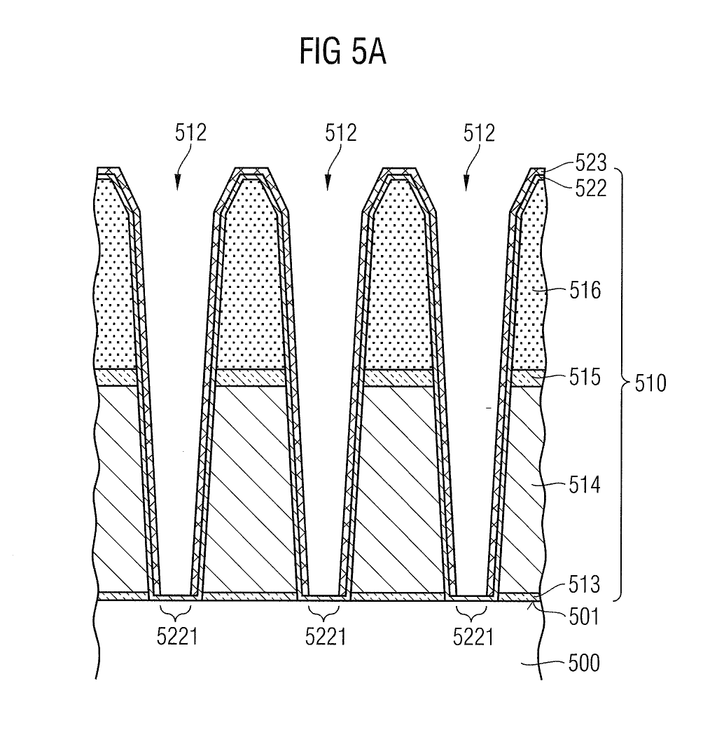

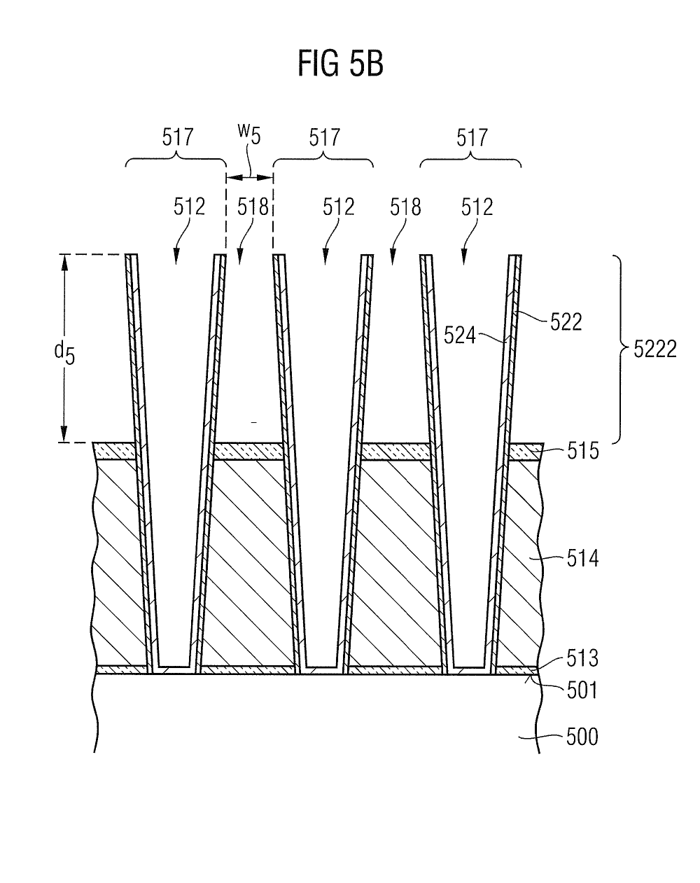

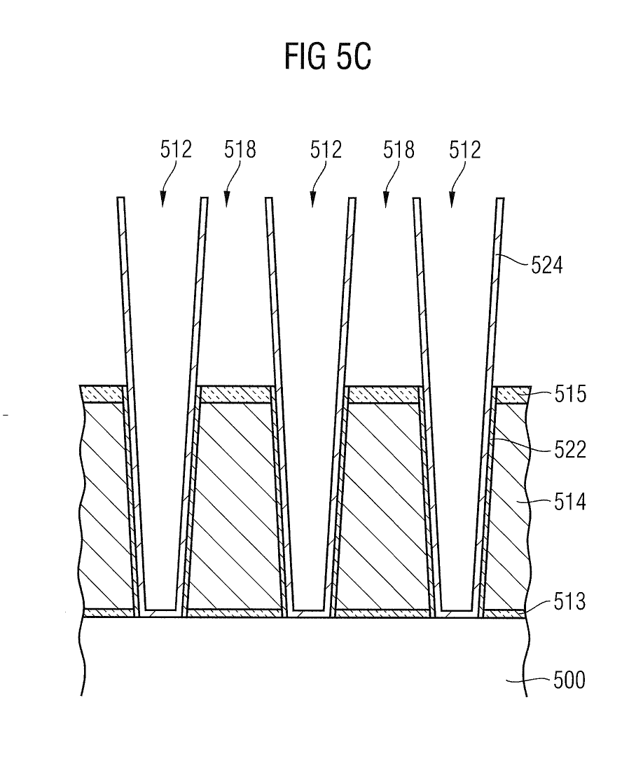

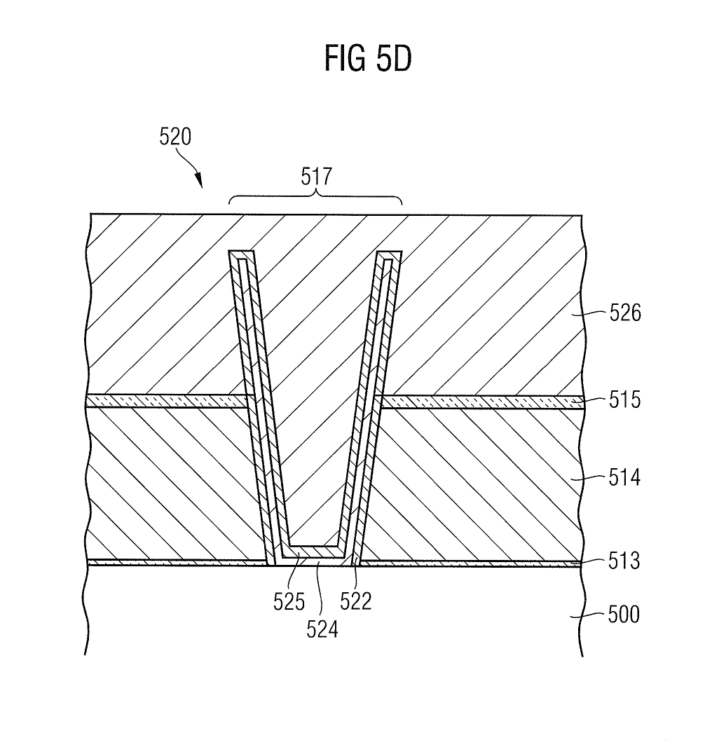

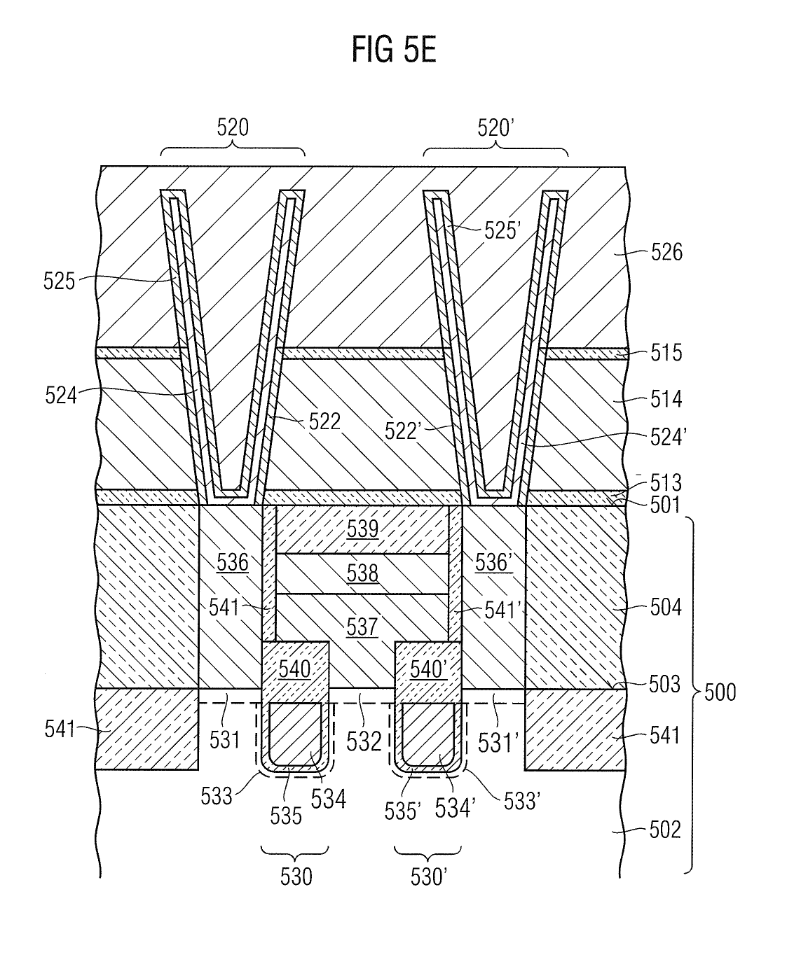

Referring to FIGS. 5A-5E, another embodiment using the described isotropic dry etch process of a high-k dielectric layer will be explained. A substrate 510 is provided on a work piece 500 having a work piece surface 501, as shown in FIG. 5A. The substrate 510 may comprise an insulating layer 513 formed on top of the workpiece surface 501, a conductive layer 514 formed on top of the insulating layer 513, an insulating layer 515 formed on top of the conductive layer 514, and a sacrificial layer 516 formed on top of the insulating layer 515. The insulating layer 513 may be made of a suitable insulating material like silicon oxide or silicon nitride. The insulating layer 513 may be a layer stack comprising insulating layers of different materials. The thickness of the insulating layer 513 may be smaller than 20 nm. The conductive layer 514 may comprise any conductive material, as for instance: a metal (e.g., W, Cu, Ir, Ru), metal nitrides (e.g., TiN or TaN), or polysilicon. The conductive layer 514 may be a layer stack comprising layers of different conductive materials. The conductive layer 514 may have a thickness of more than 500 nm. The thickness of the conductive layer 514 may be smaller than 2 μm. A typical thickness may be 1 μm. The insulating layer 515 may be made of any insulating material (e.g., silicon nitride or silicon oxide or others). The insulating layer 515 may have a thickness larger than 5 nm. The thickness of the insulating layer 515 may be smaller than 500 nm. The sacrificial layer 516 may comprise any suitable material (e.g., silicon oxide, silicon nitride or silicon oxynitride). The thickness of the sacrificial layer 516 may be more than 1 μm. A typical thickness of the sacrificial layer 516 may be 2 μm.

A plurality of trenches 512 is formed within the substrate 510, wherein the trenches 512 extend from an upper surface of the sacrificial layer 516 to the workpiece surface 501. The trenches 512 may be formed as described above. Referring to FIG. 5A, a high-k dielectric layer 522 is formed within the trenches 512 as described above. The high-k dielectric layer 522 may be formed as a conformal layer covering the whole surface of the trenches 512 including the bottom portion of the trenches 512 where the workpiece surface 501 was exposed. A masking layer 523 comprising a material as described above may be formed on the high-k dielectric layer 522 such, that a section 5221 of the high-k dielectric layer 522 remains uncovered. The section 5221 is arranged at the bottom portion of the trenches 512. The resulting structure is shown in FIG. 5A.

Subsequently, an isotropic dry etch process is performed to remove the section 5221 of the high-k dielectric layer 522 from the trenches 512. In the result, the workpiece surface 501 is exposed at the bottom portions of trenches 512. The masking material 523 may be removed as shown in FIG. 5B using, for instance, an etch process, wherein the insulating layer 515 may serve as an etch stop. Nevertheless, the masking material 523 may remain on the high-k dielectric layer 522. Subsequently, a conductive layer 524 may be formed on the high-k dielectric layer 522 within the trenches 512. The conductive layer 524 may be formed as a conformal layer covering the exposed workpiece surface 501 at the bottom portion of the trenches 512 as well. The conductive layer 524 may comprise conductive materials as described above with respect to the conductive layers of the capacitor 420 shown in FIG. 4A-4D. The high-k dielectric layer 522 and the conductive layer 524 may be formed as well on top of the sacrificial layer 516, as it is shown for the high-k dielectric layer 522 in FIG. 5A. Furthermore, as also can be seen in FIG. 5A, the sacrificial layer 516 may be eroded in an upper part by forming the trenches 512. After forming the conductive layer 524, the eroded portion of the sacrificial layer 516 may be removed together with the sections of the high-k dielectric layer 522 and the conductive layer 524 which are formed in this portion. This step may be performed for instance by filling the trenches 512 with a filling material and by planarizing the resulting structure for instance with a CMP (chemical mechanical polishing) step. Subsequently, the filling material may be removed within the trenches 512 and the sacrificial layer 516 may be removed.

The resulting structure is shown in FIG. 5B. The high-k dielectric layer 522 and the conductive layer 524 form cones 517 wherein a lower part of the cones is stabilized by the insulating layer 513, the conductive layer 514, and the insulating layer 515. In an upper portion extending from the upper surface of the insulating layer 515, the cones 517 stand free and are separated from each other by spaces 518. A section 5222 of the high-k dielectric layer 522 is exposed. A section 5222 may extend to a depth d5 measured from an upper surface of the cones 517. The depth d5 may be larger than 1 μm. The depth d5 may have a typical value of 2 μm. The spaces 518 may have a width w5 measured at the upper surface of the cones 517. The width w5 may be larger than 20 nm. The width w5 may be smaller than 90 nm. The aspect ratio of the spaces 518, that is the ratio of the depth d5 to the width w5, may be larger than 8.

Referring to FIG. 5C, the section 5222 of the high-k dielectric layer 522 is removed from the cones 517 by an isotropic dry etch process as described above. In the result, only the conductive layer 524 remains above the insulating layer 515 as shown in FIG. 5C.

Referring to FIG. 5D, a further high-k dielectric layer 525 is formed on the conductive layer 524. The further high-k dielectric layer 525 may be formed as a conformal layer on the whole exposed surface of the conductive layer 524. The further high-k dielectric layer 525 may comprise the materials, with the thicknesses, as described above with respect to the high-k dielectric layer 522. The further high-k dielectric layer 525 may comprise the same materials as the high-k dielectric layer 522. The further high-k dielectric layer 525 may have the same thickness as the high-k dielectric layer 522. The further high-k dielectric layer 525 may be formed also on top of the insulating layer 515. The further high-k dielectric layer 525 may be removed from top of the insulating layer 515 as shown in FIG. 5D or may remain on the insulating layer 515. Subsequently, a conductive material 526 is formed to fill the cones 517 and the spaces 518 between the cones 517. In FIG. 5D only one cone 517 is shown. The conductive layer 526 may comprise the materials described with respect to the conductive layer 514. The material of the conductive layer 526 may comprise the same material of the conductive layer 514 or may be a different material. According to another embodiment, a further conductive layer may be formed on the further high-k dielectric layer 525 before forming the conductive layer 526. The further conductive layer may be formed as a conformal layer and may comprise the materials and may have a thickness as described above with respect to the conductive layer 524.

Before forming the conductive layer 526, the insulating layer 515 may be removed from top of the conductive layer 514 such that an electrically conductive connection is formed between the conductive layers 514 and 526.

In another embodiment, the insulating layer 515 may remain on top of the conductive layer 514 such that the conductive layers 514 and 526 are separated from each other by the insulating layer 515, as shown in FIG. 5D. Then, the conductive layers 514 and 526 may be electrically conductive connected with each other, for instance, by a connecting structure (not shown) formed at another place of the integrated circuit.

In the result, a capacitor 520 is formed comprising a first capacitor electrode formed of the conductive layer 524 and a second capacitor electrode formed of the conductive layers 514 and 526. The first and the second capacitor electrode are separated from each other by the high-k dielectric layers 522 and 525.

Referring to FIG. 5E, two memory cells are shown, each memory cell comprising a storage capacitor 520, 520′ and an access transistor 530, 530′. The access transistors 530, 530′ are at least partially formed within a semiconductor substrate 502 being part of the workpiece 500. The workpiece 500 further comprises an insulating layer 504 formed on a surface 503 of the semiconductor substrate 502. The insulating layer 504 may comprise any suitable insulating material, for instance of silicon oxide. Each access transistor 530, 530′ comprises a first source/drain region 531, 531′ and a second source/drain region 532. The access transistors 530 and 530′ share the second source/drain region 532. A channel region 533, 533′ is formed within the semiconductor substrate 502 separating the first source/drain region 531, 531′ from the second source/drain region 532. A gate electrode 534, 534′ is formed as a buried gate electrode beneath the semiconductor substrate surface 503. Nevertheless in another embodiment, the gate electrodes 534, 534′ may be formed above the semiconductor substrate surface 503. A gate dielectric 535, 535′ insulates the gate electrode 534, 534′ from the channel region 533, 533′. The second source/drain region 532 may be coupled via a contact plug 537 to a conductive line 538 comprising a conductive material. The first source/drain regions 531, 531′ are connected via a contact plug 536, 536′ with a first capacitor electrode of the storage capacitor 520, 520′. The first capacitor electrodes are formed by the conductive layers 524, 524′. The storage capacitors 520, 520′ further comprise a second capacitor electrode formed by the conductive layers 514 and 526. The first and the second capacitor electrodes 524, 524′, 514, 526 are separated from each other by high-k dielectric layers 522, 522′, 525, 525′. The gate electrodes 534, 534′ are insulated from the contact plug 537 by an insulating material 540, 540′. The conductive line 538 is insulated from the workpiece surface 501 by an insulating material 539. The contact plugs 536, 536′ are insulated from the contact plug 537 and the conductive line 538 by an insulating material 541, 541′. The storage capacitors 520, 520′ are formed as stacked capacitors above the semiconductor substrate surface 503.

The embodiments of the invention described in the foregoing description are examples given by way of illustration and the invention is in no way limited thereto. Any modification, variation and equivalent arrangement should be considered as being included within the scope of the invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing an integrated circuit, the method comprising:
forming a trench in a substrate;
forming a high-k dielectric layer lining the trench; and
removing a section of the high-k dielectric layer from the trench via an isotropic dry etch process.

2. The method of claim 1, wherein a sidewall section of the trench, corresponding to the removed section of the high-k dielectric layer, extends in a direction having an angle of less than 5° to a direction perpendicular to a surface of the substrate.

3. The method of claim 1, wherein the high-k dielectric layer is removed from a section of the trench extending to a depth greater than 8 times a width of the trench.

4. The method of claim 1, wherein the dry etch process uses an etching chemistry based upon chlorine and borontrichloride.

5. The method of claim 1, wherein removing the section of the high-k dielectric layer from the trench further comprises:
applying a bias power of no more than 50 W to a cathode pedestal, during the dry etch process.

6. The method of claim 1, wherein removing the section of the high-k dielectric layer from the trench further comprises:
holding a cathode pedestal at a temperature of at least 300° C., during the dry etch process.

7. The method of claim 1, wherein the high-k dielectric layer comprises a silicate.

8. The method of claim 1, wherein the high-k dielectric layer comprises a metal oxide.

9. The method of claim 1, wherein the high-k dielectric layer comprises an aluminate.

10. The method of claim 1, wherein forming the high-k dielectric layer comprises:
depositing an amorphous high-k dielectric layer; and
forming a crystalline high-k dielectric layer via carrying out a process with a temperature higher than a crystallization temperature of the high-k dielectric material, before removing the section of the high-k dielectric layer.

11. The method of claim 1, further comprising:
forming a masking layer on the high-k dielectric layer, before removing the section of the high-k dielectric layer, except on the section corresponding to the section of high-k dielectric layer to be removed.

12. The method of claim 1, further comprising:
forming a first and a second capacitor electrode within the trench, wherein the high-k dielectric layer is formed between the first and second capacitor electrodes.

13. A method of manufacturing an integrated circuit, the method comprising:
forming a high-k dielectric layer on a surface of a substrate; and
removing a section of the high-k dielectric layer from the surface of the substrate, the removal of the section comprising:
using a dry etch process with an etching chemistry based upon chlorine and borontrichloride; and
applying a bias power of at most 50 W to a cathode pedestal and holding a temperature of the cathode pedestal to at least 300° C., during the dry etch process.

14. An integrated circuit comprising:
a structure formed in a substrate, the structure comprising a contour of a trench; and
a crystallized high-k dielectric layer lining the contour except in a section of the contour, the section extending to a depth greater than 8 times a width of the structure.

15. The integrated circuit of claim 14, wherein the unlined section of the contour extends from a surface of the substrate.

16. The integrated circuit of claim 14, wherein the unlined section of the contour extends in a direction having an angle of less than 5° to a direction perpendicular to a surface of the substrate.

17. The integrated circuit of claim 14, wherein the high-k dielectric layer comprises a silicate.

18. The integrated circuit of claim 14, wherein the high-k dielectric layer comprises a metal oxide.

19. The integrated circuit of claim 14, wherein the high-k dielectric layer comprises an aluminate.

20. The integrated circuit of claim 14, further comprising:
a first and a second capacitor electrode formed within the structure, wherein the high-k dielectric layer is formed between the first and the second capacitor electrode.

21. The integrated circuit of claim 20, further comprising:
a trench capacitor formed in a semiconductor substrate, the trench capacitor comprising the first and second capacitor electrodes and the high-k dielectric layer.

22. The integrated circuit of claim 20, further comprising:
a stacked capacitor formed in a substrate disposed above a semiconductor substrate; the stacked capacitor comprising the first and second capacitor electrodes and the high-k dielectric layer.

23. The integrated circuit of claim 20, further comprising:
an access transistor comprising a first and a second source/drain region, wherein the first source/drain region is electrically connected with one of the first and second capacitor electrodes.
